(19) United States
(12) Patent Application Publication
(10) Pub. No.: US 2026/0157158 A1
(43) Pub. Date: Jun. 4, 2026

(54) SEMICONDUCTOR DEVICE AND METHODS OF FABRICATING THE SAME

(71) Applicant: Samsung Electronics Co., Ltd., Suwon-si (KR)

(72) Inventors: Subin Park, Suwon-si (KR); Cheoljin Cho, Suwon-si (KR); Hyeongrae Lee, Suwon-si (KR); Youngju Kwak, Suwon-si (KR); Yoona Jang, Suwon-si (KR)

(21) Appl. No.: 19/295,792

(22) Filed: Aug. 11, 2025

(30) Foreign Application Priority Data
Dec. 4, 2024 (KR) 10-2024-0178885

(51) Int. Cl. H01L 21/762; H10D 84/01

(52) U.S. Cl. CPC H10W 10/17; H10W 10/0143; H10D 84/0135

(57) ABSTRACT

A method of manufacturing a semiconductor device. The method may include sequentially forming a pad insulation layer and a mask structure on a substrate, etching the pad insulation layer and the mask structure to form a plurality of trenches, and forming a first oxide film on the plurality of trenches. The method may further include forming a liner layer on the first oxide film, optionally with the liner layer including silicon nitride, and forming a second oxide film on the liner layer. The method may still further include forming a device isolating insulation layer covering a top surface of the substrate by changing the liner layer into an oxide through a densification process, and forming a device isolating insulation pattern that fills the plurality of trenches by removing a portion of the device isolating insulation layer through a planarization process.

### CROSS-REFERENCE TO PRIORITY APPLICATION

This application claims priority under 35 U.S.C. § 119 to Korean Patent Application No. 10-2024-0178885, filed on Dec. 4, 2024, the disclosure of which is hereby incorporated by reference herein in its entirety.

### BACKGROUND

The inventive concept relates to a semiconductor device and a method of fabricating the same, such as, but not necessarily limited to, a semiconductor device including a cell array region and a peripheral circuit region and a method of fabricating the same.

Due to the rapid developments of the electronics industry and demands of users, electronic devices are becoming smaller and lighter. Therefore, semiconductor devices with high integration levels used in electronic devices are in demand, and design rules for components of semiconductor devices are decreasing. To manufacture a semiconductor device, a trench is formed in a substrate, and a device isolating insulation pattern is formed to fill the trench. A device isolating pattern filling the trench needs to have excellent device isolating characteristics.

### SUMMARY

One aspect of inventive concept provides a semiconductor device in which a liner pattern is not disposed over a device isolating insulation pattern and a method of fabricating the same.

According to an aspect of the inventive concept, there is provided a method of manufacturing a semiconductor device, the method including sequentially forming a pad insulation layer and a mask structure on a substrate, etching the pad insulation layer and the mask structure to form a plurality of trenches, forming a first oxide film on the plurality of trenches, forming a liner layer on the first oxide film, the liner layer including silicon nitride, forming a second oxide film on the liner layer, forming a device isolating insulation layer covering a top surface of the substrate by changing the liner layer into an oxide through a densification process, and forming a device isolating insulation pattern that fills the plurality of trenches by removing a portion of the device isolating insulation layer through a planarization process.

According to another aspect of the inventive concept, there is provided a method of manufacturing a semiconductor device, the method including sequentially forming a pad insulation layer and a mask structure on a substrate, etching the pad insulation layer and the mask structure to form a plurality of trenches, forming a first oxide film conformally covering the plurality of trenches through an atomic layer deposition process on the plurality of trenches, forming a liner layer on the first oxide film, the liner layer including silicon nitride, forming a second oxide film filling the plurality of trenches through a chemical vapor deposition process on the liner layer, consuming the liner layer through a densification process, and forming a device isolating insulation pattern that fills the plurality of trenches by removing the pad insulation layer, the first oxide film, and the second oxide film.

According to another aspect of the inventive concept, there is provided a method of manufacturing a semiconductor device, the method including preparing a cell array region including a memory cell array, preparing a peripheral circuit region including a peripheral circuit transistor for transmitting a signal and power to the memory cell array, and attaching the cell array region and the peripheral circuit region in a vertical direction, wherein the preparing of the peripheral circuit region includes sequentially forming a pad insulation layer and a mask structure on a substrate, etching the pad insulation layer and the mask structure to form a plurality of trenches, forming a first oxide film conformally covering the plurality of trenches through an atomic layer deposition process on the plurality of trenches, forming a liner layer on the first oxide film, the liner layer including silicon nitride, forming a second oxide film filling the plurality of trenches through a chemical vapor deposition process on the liner layer, forming a device isolating insulation layer covering a top surface of the substrate by changing the liner layer into an oxide through a densification process, and forming a device isolating insulation pattern that fills the plurality of trenches by removing a portion of the device isolating insulation layer through a planarization process.

According to some embodiments, a semiconductor device includes a substrate including a plurality of trenches and an active region, a transistor disposed on the active region, a device isolating insulation pattern configured to fill the plurality of trenches, and a wiring structure configured to cover the transistor and the substrate. The device isolating insulation pattern includes a lower insulation pattern covering a bottom surface and a portion of a sidewall of the trenches and including silicon oxide, an upper insulation pattern covering the lower insulation pattern, filling the trenches, and including silicon oxide, and a liner pattern provided within the lower insulation pattern and including silicon nitride.

In some embodiments, 80% or more of the device isolating insulation pattern includes silicon oxide, and 95% or more of the upper insulation pattern includes silicon oxide. The device isolating insulation pattern further includes H, C, N, B, F, Cl, He, As, P, or a combination thereof. A vertical distance between a top surface of the upper insulation pattern and a top surface of the lower insulation pattern is within 50 Å. A top surface of the upper insulation pattern forms a coplanar surface with a top surface of the substrate.

In some embodiments, the plurality of trenches comprise a first trench having a first width and a second trench having a second width that is less than the first width, and the liner pattern is disposed within the first trench. A thickness of the liner pattern decreases as a distance from a bottom surface of the device isolating insulation pattern increases.

According to some embodiments, a semiconductor device includes a peripheral circuit region and a cell array region arranged at a different vertical level from that of the peripheral circuit region and attached to the peripheral circuit region. The cell array region includes a bit line extending in a first horizontal direction, a first mold layer extending in a second horizontal direction intersecting the first horizontal direction, a channel layer disposed on a sidewall of the first mold layer, a word line disposed on a sidewall of the channel layer and extending in the second horizontal direction, a capacitor structure on the first mold layer, and a contact layer provided between the channel layer and the capacitor structure. The peripheral circuit region includes a substrate including a plurality of trenches and an active region, a peripheral circuit transistor disposed on the active region, a device isolating insulation pattern filling the plurality of trenches, and a peripheral circuit wiring structure configured to cover the peripheral circuit transistor and the substrate. The device isolating insulation pattern includes a lower insulation pattern covering a bottom surface and a portion of a sidewall of the trenches and including silicon oxide, an upper insulation pattern covering the lower insulation pattern, filling the trenches, and including silicon oxide, and a liner pattern provided within the lower insulation pattern and including silicon nitride.

In some embodiments, 80% or more of the device isolating insulation pattern includes silicon oxide, and 95% or more of the upper insulation pattern includes silicon oxide. A thickness of the liner pattern decreases as a distance from a bottom surface of the device isolating insulation pattern increases.

### BRIEF DESCRIPTION OF THE DRAWINGS

Embodiments of the inventive concept will be more clearly understood from the following detailed description taken in conjunction with the accompanying diagrams in which:

FIG. 1 is a cross-sectional view of a semiconductor device according to embodiments of the present disclosure;

FIG. 2 is an enlarged cross-sectional view of a portion “EX1” of FIG. 1;

FIG. 3 is an enlarged cross-sectional view of a portion corresponding to EX1 of FIG. 1 in a semiconductor device, according to some embodiments of the present disclosure;

FIG. 4 is a schematic diagram illustrating a semiconductor device according to embodiments of the present disclosure;

FIG. 5 is an enlarged layout view of a cell array region of FIG. 4;

FIG. 6 is a cross-sectional view taken along a line A1-A1′ of FIG. 5; and

FIGS. 7 to 15 are cross-sectional views showing a method of fabricating a semiconductor device, according to embodiments of the present disclosure.

### DETAILED DESCRIPTION OF THE EMBODIMENTS

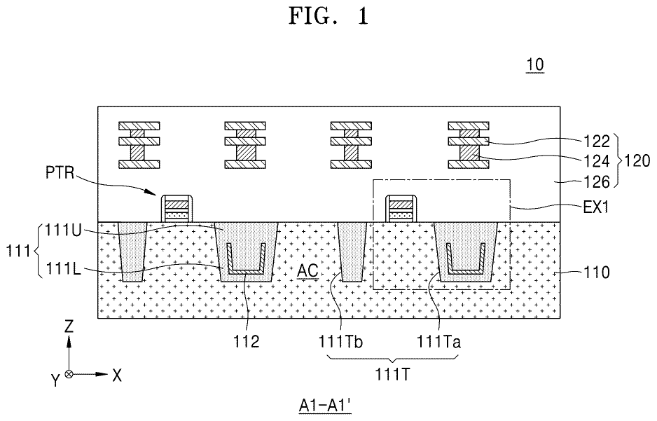

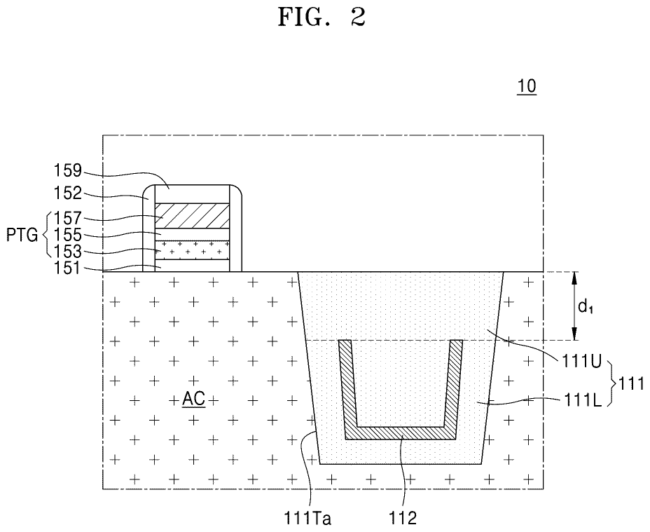

FIG. 1 is a cross-sectional view of a semiconductor device 10 according to embodiments of the present disclosure. FIG. 2 is an enlarged cross-sectional view of a portion “EX1” of FIG. 1.

Referring to FIGS. 1 and 2, the semiconductor device 10 according to the inventive concept may include a substrate 110, in which an active region AC is defined, and a wiring structure 120. The substrate 110 includes a plurality of trenches 111T, and the plurality of trenches 111T may define the active region AC.

According to embodiments of the present disclosure, the substrate 110 may include silicon, e.g., monocrystalline silicon, polycrystalline silicon, or amorphous silicon. According to some other embodiments of the present disclosure, the substrate 110 may include at least one selected from among Ge, SiGe, SiC, GaAs, InAs, and InP. According to some embodiments of the present disclosure, the substrate 110 may include a conductive region, e.g., a well doped with an impurity or a structure doped with an impurity.

According to embodiments of the present disclosure, the plurality of trenches 111T may include a first trench 111Ta and a second trench 111Tb. Horizontal widths of the plurality of trenches 111T may be different from each other. For example, the horizontal width of the first trench 111Ta may be greater than the horizontal width of the second trench 111Tb.

According to embodiments of the present disclosure, a device isolating insulation pattern 111 may fill the plurality of trenches 111T. At this time, the device isolating insulation pattern 111 may be a silicon oxide film formed through chemical vapor deposition (CVD), atomic layer deposition (ALD), Tonen SilaZen (TOSZ) coating, thermal oxidation, or a combination thereof.

According to embodiments of the present disclosure, the device isolating insulation pattern 111 may include a lower insulation pattern 111L, an upper insulation pattern 111U, and a liner pattern 112. The lower insulation pattern 111L may cover the bottom surface and a portion of sidewalls of the trench 111T. The upper insulation pattern 111U may cover the lower insulation pattern 111L and fill the remaining space of the trench 111T. The liner pattern 112 may be provided within the lower insulation pattern 111L. At this time, the lower insulation pattern 111L and the upper insulation pattern 111U may include silicon oxide, and the liner pattern 112 may include silicon nitride.

According to embodiments of the present disclosure, the liner pattern 112 may have a U-shaped vertical cross-section. At this time, the thickness of the liner pattern 112 may be 70 Å or less, but the inventive concept is not limited thereto. The thickness of the liner pattern 112 may decrease away from the bottom surface of the device isolating insulation pattern 111.

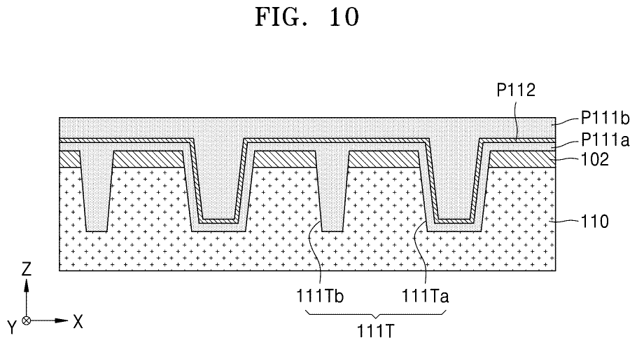

According to embodiments of the present disclosure, the liner pattern 112 may be provided within the first trench 111Ta and may not be provided within the second trench 111Tb. In the case of the second trench 111Tb having a relatively smaller width, a liner layer P112 (refer to FIG. 10) is not formed during the process, and thus the liner pattern 112 may not be provided.

According to embodiments of the present disclosure, more than 80% of the device isolating insulation pattern 111 may include silicon oxide (SiO₂). At this time, 95% or more of the upper insulation pattern 111U may include SiO₂. Unlike the lower insulation pattern 111L, there is no liner pattern 112 in the upper insulation pattern 111U, and thus 95% or more of the upper insulation pattern 111U may include SiO₂. At this time, the device isolating insulation pattern 111 may further include H, C, N, B, F, Cl, He, As, P, or a combination thereof.

According to embodiments of the present disclosure, a height d₁ of the upper insulation pattern 111U may be about 50 Å. At this time, the height d₁ of the upper insulation pattern 111U may mean a distance in a vertical direction (Z direction) from the top surface of the upper insulation pattern 111U to the top surface of the lower insulation pattern 111L. Optionally, a vertical distance between a topmost portion of the liner pattern 112 and a top surface of the device isolating insulation pattern may be within 50 Å.

According to embodiments of the present disclosure, the wiring structure 120 may be arranged on the substrate 110. The wiring structure 120 may include a wire 122, a contact 124, and an insulation layer 126. The wire 122 and the contact 124 may be electrically connected to a transistor PTR and/or the substrate 110, and the insulation layer 126 may cover the transistor PTR, the wire 122, and the contact 124 on the substrate 110. The insulation layer 126 may include an oxide film, a nitride film, a low-k dielectric film, or a combination thereof, and may be formed as a stacked structure of a plurality of insulation layers.

According to embodiments of the present disclosure, the transistor PTR may be disposed on the active region AC. The transistor PTR may include a gate electrode PTG, a gate insulation pattern 151, a gate capping pattern 159, an insulation spacer 152, and a source/drain region (not shown).

In detail, the gate electrode PTG may include a first conductive pattern 153, a second conductive pattern 155, and a third conductive pattern 157 arranged on the gate insulation pattern 151. At this time, the gate electrode PTG may be covered with the gate capping pattern 159. The insulation spacer 152 may cover side surfaces of the gate insulation pattern 151, the gate electrode PTG, and the gate capping pattern 159.

According to embodiments of the present disclosure, the gate insulation pattern 151 may include at least one selected from among a silicon oxide film, a silicon nitride film, a silicon oxynitride film, an oxide/nitride/oxide (ONO) film, and a high-k dielectric film having a dielectric constant that is higher than that of the silicon oxide film. According to some embodiments of the present disclosure, the insulation spacer 152 may include, but is not limited to, a silicon oxide film, a silicon nitride film, or a combination thereof.

According to embodiments of the present disclosure, the semiconductor device 10 according to the inventive concept may not have a liner pattern 112 provided above the device isolating insulation pattern 111. In detail, the liner pattern 112 may not be provided in the upper insulation pattern 111U. Since the liner pattern 112 is not disposed within the upper insulation pattern 111U, the top surface of the device isolating insulation pattern 111 may form a coplanar shape.

In the case of a semiconductor device according to a comparative example, a dent is formed between a liner pattern and a device isolating insulation pattern, and thus, during the process of forming a gate electrode, impurities cover the dent, thereby causing a problem of lowering the reliability and structural stability of the semiconductor device.

As disclosed herein, since the semiconductor device 10 according to the inventive concept does not have the liner pattern 112 disposed within the upper insulation pattern 111U, the top surface of the device isolating insulation pattern 111 forms a coplanar shape, such as with a top surface of the substrate 110, and does not form a recessed portion, thereby preventing defects occurring during the process of forming the gate electrode PTG. Therefore, the reliability and the structural stability of the semiconductor device 10 may be improved.

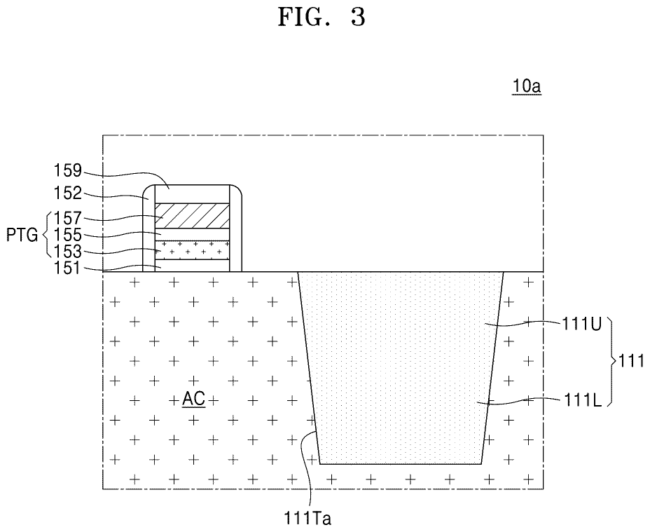

FIG. 3 is an enlarged cross-sectional view of a portion corresponding to EX1 of FIG. 1 in a semiconductor device 10a, according to some embodiments of the present disclosure. In the description with reference to FIG. 3, the same reference numerals as those of the semiconductor device 10 described with reference to FIGS. 1 and 2 denote substantially the same components, and thus detailed descriptions thereof are omitted.

Referring to FIG. 3, in the semiconductor device 10a according to the inventive concept, the device isolating insulation pattern 111 may fill the plurality of trenches 111T. At this time, the device isolating insulation pattern 111 may be a silicon oxide film formed through CVD, ALD, TOSZ coating, thermal oxidation, or a combination thereof.

According to embodiments of the present disclosure, the device isolating insulation pattern 111 may include the lower insulation pattern 111L and the upper insulation pattern 111U. The lower insulation pattern 111L may cover the bottom surface and a portion of sidewalls of the trench 111T. The upper insulation pattern 111U may cover the lower insulation pattern 111L and fill the remaining space of the trench 111T. At this time, the lower insulation pattern 111L and the upper insulation pattern 111U may include silicon oxide.

According to embodiments of the present disclosure, the device isolating insulation pattern 111 may not include the liner pattern 112 (refer to FIG. 2). In detail, not only the upper insulation pattern 111U but also the lower insulation pattern 111L may not include the liner pattern 112. Therefore, the top surface of the device isolating insulation pattern 111 may form a coplanar surface.

Since the semiconductor device 10a according to the inventive concept does not have the liner pattern 112 disposed within the device isolating insulation pattern 111, the top surface of the device isolating insulation pattern 111 forms a coplanar shape and does not form a recessed portion, thereby preventing defects occurring during the process of forming the gate electrode PTG. Therefore, the reliability and the structural stability of the semiconductor device 10a may be improved.

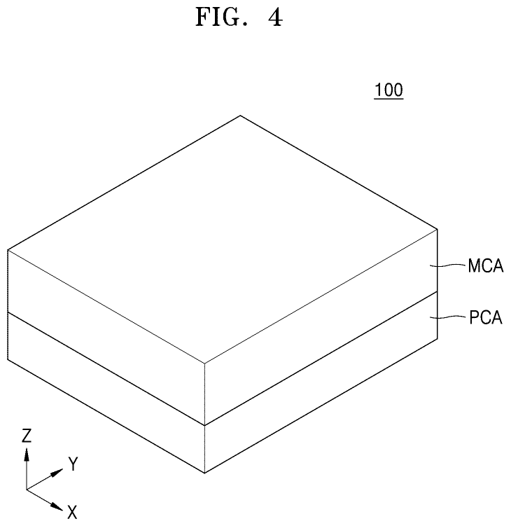

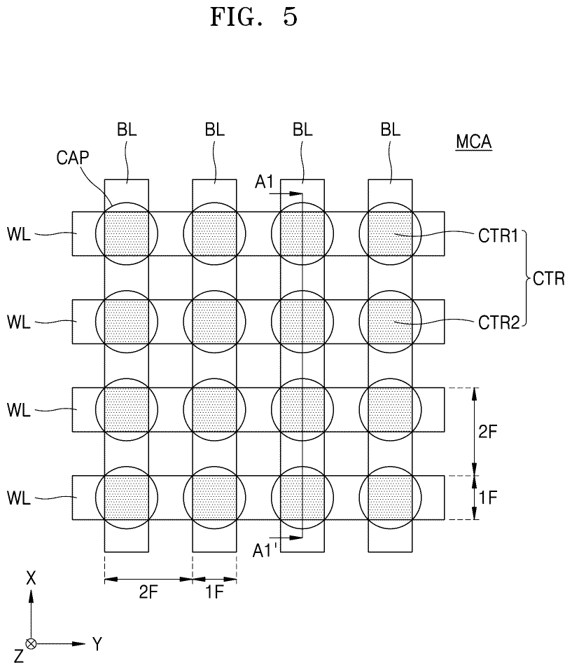

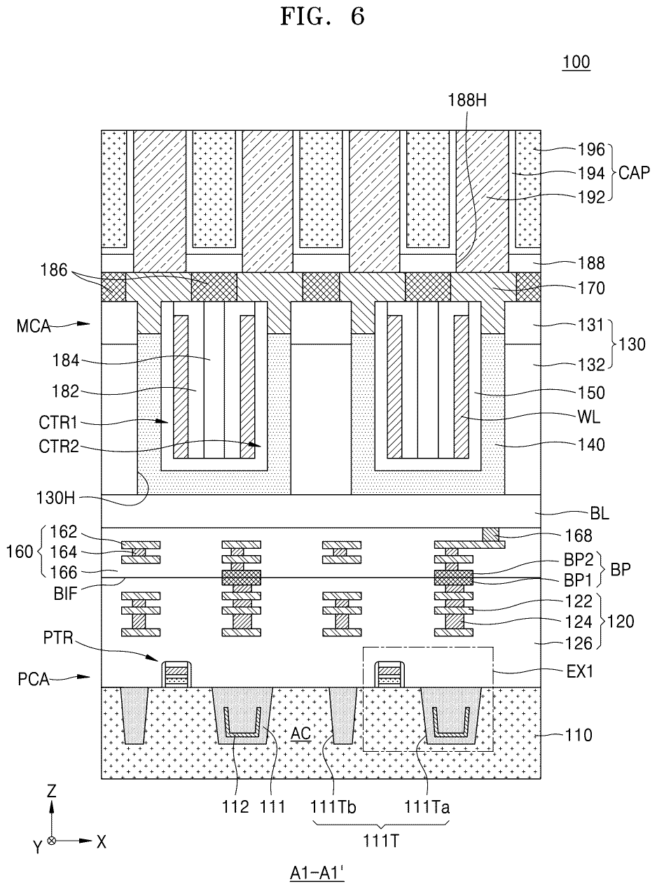

FIG. 4 is a schematic diagram illustrating a semiconductor device 100 according to embodiments of the present disclosure. FIG. 5 is an enlarged layout view of a cell array region MCA of FIG. 4. FIG. 6 is a cross-sectional view taken along a line A1-A1′ of FIG. 5.

Referring to FIGS. 4 to 6, the semiconductor device 100 may include the cell array region MCA and a peripheral circuit region PCA. The cell array region MCA may be disposed at a higher vertical level than the peripheral circuit region PCA, but the inventive concept is not limited thereto. For example, the cell array region MCA may be disposed at a lower vertical level than the peripheral circuit region PCA.

According to embodiments of the present disclosure, the cell array region MCA may be a memory cell region of a DRAM device, and the peripheral circuit region PCA may be a core region or a peripheral circuit region of the DRAM device. For example, the peripheral circuit region PCA may include the peripheral circuit transistor PTR for transmitting a signal and/or power to a memory cell array included in the cell array area MCA. According to embodiments of the present disclosure, the peripheral circuit transistor PTR may configure various circuits like a command decoder, control logic, an address buffer, a row decoder, a column decoder, a sense amplifier, and a data input/output circuit.

As shown in FIG. 5, a plurality of bit lines BL extending in a first horizontal direction (X direction) and a plurality of word lines WL extending in a second horizontal direction (Y direction) may be arranged in the cell array region MCA. A plurality of cell transistors CTR may be arranged at intersections of the plurality of word lines WL and the plurality of bit lines BL. A plurality of cell capacitors CAP may comprise a capacitor structure and may be arranged on the plurality of cell transistors CTR, respectively.

According to embodiments of the present disclosure, the plurality of word lines WL may be alternately arranged in the first horizontal direction (X direction). The plurality of cell transistors CTR may include a first cell transistor CTR1 and a second cell transistor CTR2 that are alternately arranged in the first horizontal direction (X direction). The first cell transistor CTR1 and the second cell transistor CTR2 may be respectively arranged on the plurality of word lines WL.

According to embodiments of the present disclosure, the first cell transistor CTR1 and the second cell transistor CTR2 may have mirror-image symmetric structures with respect to each other. For example, the first cell transistor CTR1 and the second cell transistor CTR2 may have a mirror-symmetrical structure around the center line between the first cell transistor CTR1 and the second cell transistor CTR2 extending in the second horizontal direction (Y direction).

According to embodiments of the present disclosure, the width of the plurality of word lines WL may be 1F, the pitch (i.e., the sum of the width and the spacing) of the plurality of word lines WL may be 2F, the width of the plurality of bit lines BL may be 1F, the pitch (i.e., the sum of the width and the spacing) of the plurality of bit lines BL may be 2F, and an unit area for forming one cell transistor CTR may be 4F². Therefore, since the cell transistor CTR may be of a cross-point type that needs a relatively small unit area, the integration of the semiconductor device 100 may be improved.

Although not shown, an edge region may be placed around the periphery of the cell array region MCA. An edge region may be a region where an electrical connection member for a word line WL and/or an electrical connection member for a bit line BL is/are disposed, and may be a region where an electrical connection member that enables electrical connection between the cell array region MCA and the peripheral circuit region PCA is disposed.

According to embodiments of the present disclosure, the peripheral circuit region PCA may correspond to a semiconductor device 10 or 10a described with reference to FIGS. 1 to 3. Therefore, the same reference numerals as those of the semiconductor device 10 or 10a described with reference to FIGS. 1 to 3 denote substantially the same components, and thus detailed descriptions thereof are omitted.

According to embodiments of the present disclosure, in the peripheral circuit region PCA, the active region AC may be defined on the substrate 110, and the peripheral circuit transistor PTR may be placed on the active region AC of the substrate 110. The peripheral circuit transistor PTR may include the gate electrode PTG, the gate insulation pattern 151, and the source/drain region (not shown).

According to embodiments of the present disclosure, the plurality of trenches 111T may include the first trench 111Ta and the second trench 111Tb. At this time, the device isolating insulation pattern 111 may fill the plurality of trenches 111T.

According to embodiments of the present disclosure, the device isolating insulation pattern 111 may include the lower insulation pattern 111L, the upper insulation pattern 111U, and the liner pattern 112. At this time, the lower insulation pattern 111L and the upper insulation pattern 111U may include silicon oxide, and the liner pattern 112 may include silicon nitride. According to some embodiments of the present disclosure, the liner pattern 112 may be omitted (refer to FIG. 3).

According to embodiments of the present disclosure, the semiconductor device 100 according to the inventive concept may not have the liner pattern 112 provided above the device isolating insulation pattern 111. In detail, the liner pattern 112 may not be provided in the upper insulation pattern 111U. Since the liner pattern 112 is not disposed within the upper insulation pattern 111U, the top surface of the device isolating insulation pattern 111 may form a coplanar shape.

As disclosed herein, since the semiconductor device 100 according to the inventive concept does not have the liner pattern 112 disposed within the upper insulation pattern 111U, the top surface of the device isolating insulation pattern 111 forms a coplanar shape and does not form a recessed portion, thereby preventing defects occurring during the process of forming the gate electrode PTG. Therefore, the reliability and the structural stability of the semiconductor device 100 may be improved.

According to embodiments of the present disclosure, the peripheral circuit wiring structures 120 may be arranged on the substrate 110. The peripheral circuit wiring structure 120 may include a peripheral circuit wire 122, a peripheral circuit contact 124, and a peripheral circuit insulation layer 126. The peripheral circuit wire 122 and the peripheral circuit contact 124 may be electrically connected to the peripheral circuit transistor PTR and/or the substrate 110, and the peripheral circuit insulation layer 126 may cover the peripheral circuit transistor PTR, the peripheral circuit wire 122, and the peripheral circuit contact 124 on the substrate 110. The peripheral circuit insulation layer 126 may include an oxide film, a nitride film, a low-k dielectric film, or a combination thereof, and may be formed as a stacked structure of a plurality of insulation layers.

According to embodiments of the present disclosure, the peripheral circuit region PCA may be attached to the cell array region MCA in a bonding manner. According to embodiments of the present disclosure, the boundary between the peripheral circuit region PCA and the cell array region MCA may be referred to as a bonding interface BIF. For example, a portion of the semiconductor device 100 that is at a lower vertical level than the bonding interface BIF shown in FIG. 6 may be referred to as the peripheral circuit region PCA, and a portion of the semiconductor device 100 that is at a higher vertical level than the bonding interface BIF may be referred to as the cell array region MCA.

According to embodiments of the present disclosure, the peripheral circuit wiring structure 120 and a cell wiring structure 160 may contact each other with the bonding interface BIF therebetween. The cell wiring structure 160 may include a cell wiring layer 162, a cell contact 164, a cell insulation layer 166, and a bit line contact 168. The bit line contact 168 may electrically connect the cell wiring structure 160 and the bit line BL to each other.

According to embodiments of the present disclosure, a bonding pad BP may be placed at the bonding interface BIF of the cell wiring structure 160 and the peripheral circuit wiring structure 120. The bonding pad BP may include a first bonding pad BP1 and a second bonding pad BP2. The top surface of the first bonding pad BP1 may be at the same level as the top surface of the peripheral circuit insulation layer 126, and the bottom surface of the second bonding pad BP2 may be at the same level as the bottom surface of the cell insulation layer 166. The top surface of the first bonding pad BP1 may contact the bottom surface of the second bonding pad BP2.

According to embodiments of the present disclosure, the cell wiring structure 160 and the peripheral circuit wiring structure 120 may be bonded to each other through metal-oxide hybrid bonding. The boundary between the peripheral circuit insulation layer 126 and the cell insulation layer 166 may be disposed on the same plane as the boundary between the first bonding pad BP1 and the second bonding pad BP2. For example, the boundary between the peripheral circuit insulation layer 126 and the cell insulation layer 166 and the boundary between the first bonding pad BP1 and the second bonding pad BP2 may be arranged along the bonding interface BIF.

According to embodiments of the present disclosure, the cell wiring structure 160 and the peripheral circuit wiring structure 120 may be bonded through oxide bonding, in which case the bonding pad BP may be omitted.

A bit line BL extending in the first horizontal direction (X direction) may be disposed on the cell wiring structure 160. According to embodiments of the present disclosure, the bit line BL may include Ti, TiN, Ta, TaN, W, WN, TiSiN, WSiN, polysilicon, or a combination thereof. For example, the bit line BL may include a conductive layer (not shown) and a conductive barrier layer (not shown) disposed on the top surface and the bottom surface of the conductive layer.

According to embodiments of the present disclosure, a first mold layer 130 may be disposed on the bit line BL. The first mold layer 130 may include a plurality of mold openings 130H. The top surface of the bit line BL may be exposed at the bottom of the plurality of openings 130H.

According to embodiments of the present disclosure, the first mold layer 130 may include at least one of silicon oxide, silicon nitride, and silicon oxynitride. The first mold layer 130 may be formed as a multi-layer structure. For example, the first mold layer 130 may include a first insulation film 131 and a second insulation film 132.

According to embodiments of the present disclosure, the second insulation film 132 may be disposed on the bit line BL. The first insulation film 131 may be placed on the second insulation film 132. Although FIG. 6 shows that the first mold layer 130 includes two insulation films, the inventive concept is not limited thereto. For example, the first mold layer 130 may be formed as a single-film structure or may include three or more films.

According to embodiments of the present disclosure, a plurality of channel layers 140 may be arranged on the inner walls of the plurality of mold openings 130H. The plurality of channel layers 140 may each cover sidewalls and bottom surfaces of the plurality of mold openings 130H. For example, the plurality of channel layers 140 may each have a U-shaped vertical cross-section.

According to embodiments of the present disclosure, the plurality of channel layers 140 may include first sidewalls and second sidewalls opposite to each other. The first sidewalls may be in contact with the gate insulation layer 150, and the second sidewalls may be in contact with the first mold layer 130. Also, the top surfaces of the plurality of channel layers 140 may each be at a lower level than the top surface of the first mold layer 130.

According to embodiments of the present disclosure, the plurality of channel layers 140 may include an oxide semiconductor material. For example, the plurality of channel layers 140 may include InO, ZnO GaO, IGO, ITO, IGZO, ITGO, IAZO, or a combination thereof. According to embodiments of the present disclosure, the plurality of channel layers 140 may include an oxide semiconductor material containing indium. For example, the oxide semiconductor material may include at least one of InGaZnOx (IGZO), Sn-doped InGaZnOx (Sn-doped IGZO), W-doped InGaZnOx (W-doped IGZO), and InZnOx (IZO).

According to embodiments of the present disclosure, the gate insulation layer 150 and the word line WL may be sequentially arranged on the sidewalls of each of the plurality of channel layers 140. The gate insulation layer 150 may be conformally arranged on the top surface and sidewalls of the plurality of channel layers 140.

According to embodiments of the present disclosure, the word line WL may be disposed on a sidewall of the gate insulation layer 150. In other words, the gate insulation layer 150 may be provided between the word line WL and the channel layer 140. The word line WL may extend in the second horizontal direction (Y direction) within the mold opening 130H. A pair of word lines WL may be arranged spaced apart from each other in the first horizontal direction (X direction) on the channel layer 140 within one mold opening 130H. The word line WL may include Ti, TiN, Ta, TaN, W, WN, TiSiN, WSiN, polysilicon, or a combination thereof.

According to embodiments of the present disclosure, the gate insulation layer 150 may include at least one selected from a high-k dielectric material and a ferroelectric material having a dielectric constant higher than that of silicon oxide. According to some embodiments of the present disclosure, the gate insulation layer 150 may include at least one material selected from the group consisting of among hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and lead scandium tantalum oxide (PbScTaO).

According to embodiments of the present disclosure, an insulation liner 182 and a first insulation layer 184 may be placed between the pair of word lines WL within each of the plurality of mold openings 130H. A plurality of insulation liners 182 may be placed on each of the word lines WL. The first insulation layer 184 is placed between the plurality of insulation liners 182 and may have a column-like cross-section. However, the shapes of the insulation liner 182 and the first insulation layer 184 are not limited thereto and may be designed in various ways as one skilled in the art will appreciate.

According to embodiments of the present disclosure, a contact layer 170 may be formed on the channel layer 140. For example, the contact layer 170 may be connected to the top surface of the channel layer 140. According to some embodiments of the present disclosure, the lowermost portion of the contact layer 170 may be located at a vertical level lower than that of the top surface of the word line WL.

According to embodiments of the present disclosure, the contact layer 170 may electrically connect the channel layer 140 to a cell capacitor CAP. The contact layer 170 may include, but is not limited to, at least one of a conductive material, e.g., a metal, a conductive metal nitride, a conductive metal carbonitride, a conductive metal carbide, a metal silicide, a doped semiconductor material, a conductive metal oxynitride, and a conductive metal oxide, and a two-dimensional (2D) material.

According to embodiments of the present disclosure, second insulation layers 186 may be arranged on both sidewalls of the contact layer 170. Although it is shown that the top surfaces of the second insulation layers 186 and the top surfaces of a plurality of contact layers 170 are at the same level, the inventive concept is not limited thereto. For example, the top surfaces of the second insulation layers 186 may be at a higher level than the top surfaces of the plurality of contact layers 170.

According to embodiments of the present disclosure, the insulation liner 182 may include silicon nitride and the first insulation layer 184 may include silicon oxide. A second insulation layer 186 may include silicon nitride.

According to embodiments of the present disclosure, an etch stop film 188 may be disposed on the contact layer 170 and the second insulation layer 186. The etch stop film 188 may include an opening 188H, and the top surface of the contact layer 170 may be exposed at the bottom of the opening 188H.

According to embodiments of the present disclosure, a cell capacitor CAP may be disposed on the etch stop film 188. The cell capacitor CAP may include a lower electrode 192, a capacitor dielectric layer 194, and an upper electrode 196. The sidewall of the bottom portion of the lower electrode 192 may be disposed within an opening 188H of the etch stop layer 188, and the lower electrode 192 may extend in the vertical direction (Z direction). The capacitor dielectric layer 194 may be disposed on the sidewall of the lower electrode 192, and the upper electrode 196 may cover the lower electrode 192 on the capacitor dielectric layer 194.

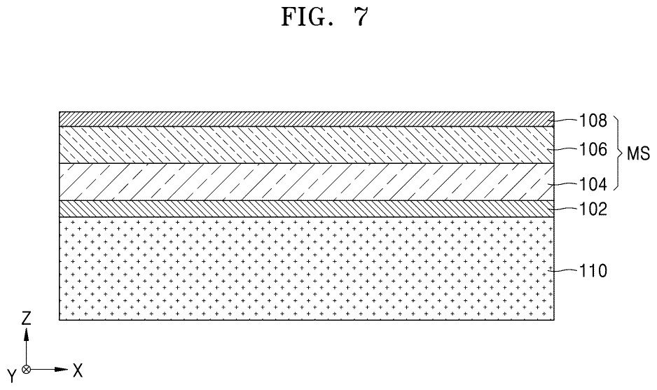

FIGS. 7 to 15 are cross-sectional views showing a method of fabricating the semiconductor device 10, according to embodiments of the present disclosure. In the descriptions with reference to FIGS. 7 to 15, the same reference numerals as those of the semiconductor device 10 described with reference to FIGS. 1 and 2 denote substantially the same components, and thus detailed descriptions thereof are omitted.

Referring to FIG. 7, a pad insulation layer 102 and a mask structure MS may be formed on the substrate 110. The mask structure MS may include a first mask layer 104, a second mask layer 106, and a third mask layer 108. The first mask layer 104, the second mask layer 106, and the third mask layer 108 may be sequentially stacked on the pad insulation layer 102. The pad insulation layer 102 and the mask structure MS may be formed through a CVD process, etc.

According to embodiments of the present disclosure, the pad insulation layer 102 may include silicon nitride. The first mask layer 104, the second mask layer 106, and the third mask layer 108 may each include silicon nitride, silicon oxide, an insulation material, or a combination thereof. For example, the first mask layer 104 may include silicon oxide. The second mask layer 106 may be an amorphous carbon layer including amorphous carbon. The third mask layer 108 may include silicon nitride.

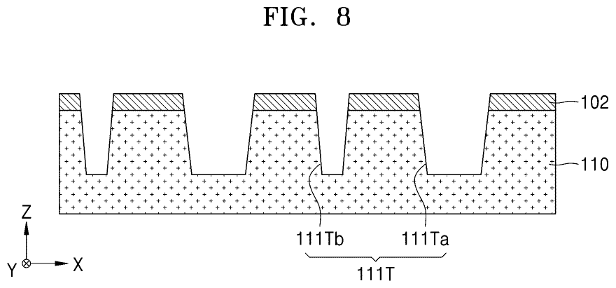

Referring to FIG. 8, a mask pattern is formed on the mask structure MS, and the mask structure MS, the pad insulation layer 102, and the substrate 110 may be etched by using the mask pattern to form the plurality of trenches 111T. The etching process may include an anisotropic etching process. Afterwards, the mask structure MS may be removed.

According to embodiments of the present disclosure, the plurality of trenches 111T may include the first trench 111Ta and the second trench 111Tb. Horizontal widths of the plurality of trenches 111T may be different from each other. For example, the horizontal width of the first trench 111Ta may be greater than the horizontal width of the second trench 111Tb. The pad insulation layer 102 may cover the top surface of the substrate 110 in which the trench 111T is not formed.

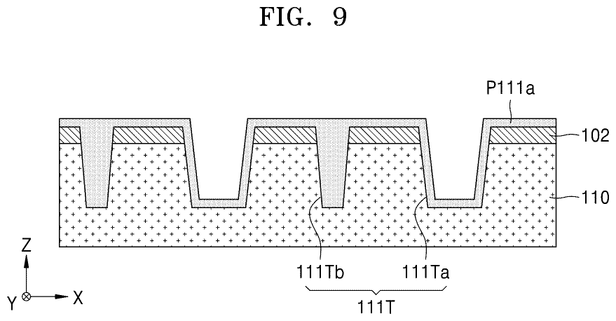

Referring to FIG. 9, a first oxide film P111a may be formed on a resulting structure of FIG. 8. The first oxide film P111a may include silicon oxide. The first oxide film P111a may be conformally formed to cover the top surface of the substrate 110 and the plurality of trenches 111T. For example, the first oxide film P111a may be formed conformally along the surfaces of the plurality of trenches 111T. The first oxide film P111a may be formed through an ALD process.

According to embodiments of the present disclosure, the first oxide film P111a may cover the plurality of trenches 111T. At this time, in the case of the first trench 111Ta having a larger width, the first oxide film P111a may cover the bottom surface and sidewalls of the first trench 111Ta. In the case of the second trench 111Tb having a smaller width, the first oxide film P111a may cover the bottom surface and sidewalls of the second trench 111Tb to fill the space of the second trench 111Tb.

Referring to FIG. 10, a liner layer P112 and a second oxide film P111b may be formed in a resulting structure of FIG. 9. The liner layer P112 may cover the top surface of the first oxide film P111a. In other words, the liner layer P112 may be formed along the profile of the top surface of the first oxide film P111a. For example, the liner layer P112 may be formed spaced apart from the bottom surface and sidewalls of the first trench 111Ta with the first oxide film P111a therebetween. At this time, the thickness of the liner layer P112 may be 50 Å, but the inventive concept is not limited thereto. For example, the thickness of the liner layer P112 may be 50 Å or greater.

According to embodiments of the present disclosure, the liner layer P112 may not be formed inside the second trench 111Tb. In the case of the second trench 111Tb having a smaller width, since the first oxide film P111a fills all the space of the second trench 111Tb, the liner layer P112 may be formed on the first oxide film P111a covering the second trench 111Tb.

According to embodiments of the present disclosure, the second oxide film P111b may be formed to cover the liner layer P112. The second oxide film P111b may include silicon oxide. For example, the second oxide film P111b may include TOSZ, but the inventive concept is not limited thereto.

According to embodiments of the present disclosure, the second oxide film P111b may be formed through a CVD process. The second oxide film P111b covers the liner layer P112 and may fill the spaces of the plurality of trenches 111T. For example, the second oxide film P111b may cover the bottom surface and sidewalls of the first trench 111Ta and fill the space of the first trench 111Ta.

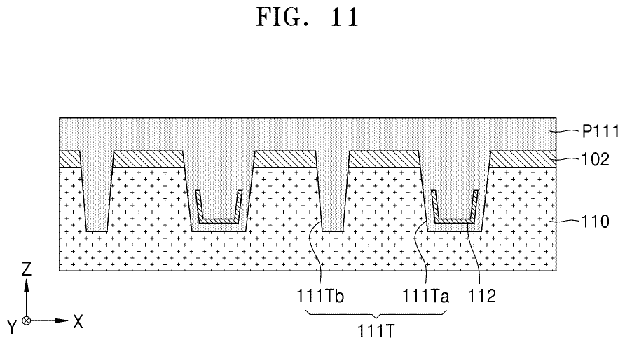

Referring to FIG. 11, the liner layer P112 (refer to FIG. 10) may be consumed through a densification process. The densification process may include a process of increasing the density of a thin film (e.g., the first oxide film P111a, the liner layer P112, and the second oxide film P111b) through a high temperature treatment. For example, the densification process may include a thermal oxidation process, by which the liner layer P112 may be changed into an oxide.

According to embodiments of the present disclosure, the liner layer P112 is changed into an oxide through the densification process, and the first oxide film P111a (refer to FIG. 10) and the second oxide film P111b (refer to FIG. 10) may form a device isolating insulation layer P111. The device isolating insulation layer P111 may be a silicon oxide film formed through a thermal oxidation process.

According to embodiments of the present disclosure, when the liner layer P112 is changed to an oxide through the densification process, some of the liner layer P112 may remain to form the liner pattern 112. The liner pattern 112 may be provided under the device isolating insulation layer P111. For example, the amount of the liner layer P112 that is changed to an oxide may increase as a distance from the bottom surface of the first trench 111Ta increases. In an upper portion of the first trench 111Ta, the liner layer P112 may be completely consumed and changed into an oxide, and, in a lower portion of the first trench 111Ta, the liner layer P112 may be partially consumed and changed into an oxide. Therefore, the liner pattern 112 may be provided adjacent to the bottom surface of the first trench 111Ta. At this time, since the liner pattern 112 is formed by changing a portion of the liner layer P112 into an oxide, the thickness of the liner pattern 112 may be less than the thickness of the liner layer P112.

According to embodiments of the present disclosure, when the liner layer P112 is changed to an oxide through the densification process, the thickness of the liner layer P112 may be reduced by about 50 Å. For example, when the thickness of the liner layer P112 is about 50 Å, the liner pattern 112 may not be formed depending on the assembly process. When the thickness of the liner layer P112 is about 100 Å, the thickness of a portion of the liner pattern 112 remaining after the assembly process may be about 50 Å. The thickness of the remaining liner pattern 112 may be designed to be 70 Å or less.

According to some embodiments of the present disclosure, the liner layer P112 may be entirely converted to an oxide through the densification process. In this case, the liner pattern 112 may not remain inside the device isolating insulation layer P111 (refer to FIG. 3).

According to embodiments of the present disclosure, when the liner layer P112 is changed to an oxide through the densification process, the volume of the liner layer P112 may increase. When a silicon nitride (e.g., Si₃N₄) is converted to a silicon oxide (e.g., SiO₂), the oxidation volume increase rate may be about 155%. In a method of fabricating a semiconductor device according to a comparative example, when silicon (e.g., Si) is changed into a silicon oxide (e.g., SiO₂), the oxidation volume increase rate may be about 189%. According to the method of fabricating a semiconductor device 10 according to the inventive concept, the volume increase rate is relatively small, the stress applied to the trench 111T and the substrate 110 when the liner layer P112 changes to an oxide through a densification process is reduced, and thus the structural stability of the semiconductor device 10 may be increased.

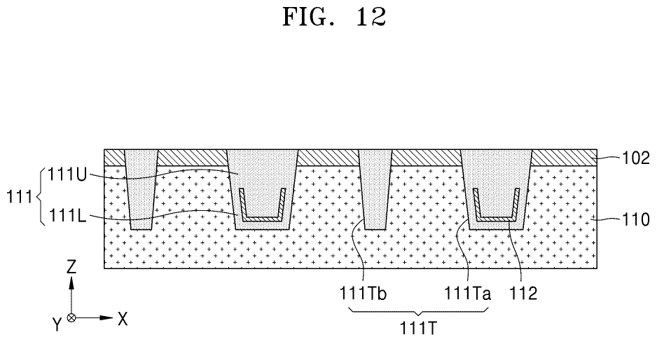

Referring to FIG. 12, a portion of the device isolating insulation layer P111 may be removed through a planarization process (e.g., a chemical mechanical planarization (CMP) process) to form the device isolating insulation pattern 111. The device isolating insulation pattern 111 may fill the plurality of trenches 111T. The device isolating insulation pattern 111 may be a silicon oxide film formed through a thermal oxidation process.

According to embodiments of the present disclosure, the device isolating insulation pattern 111 may include the lower insulation pattern 111L, the upper insulation pattern 111U, and the liner pattern 112. The lower insulation pattern 111L may cover the bottom surface and a portion of sidewalls of the trench 111T. The upper insulation pattern 111U may cover the lower insulation pattern 111L and fill the remaining space of the trench 111T. The liner pattern 112 may be provided within the lower insulation pattern 111L. At this time, the lower insulation pattern 111L and the upper insulation pattern 111U may include silicon oxide, and the liner pattern 112 may include silicon nitride.

According to embodiments of the present disclosure, the top surface of the pad insulation layer 102 may become coplanar with the top surface of the device isolating insulation pattern 111 through the planarization process. At this time, the pad insulation layer 102 may act as a barrier in the planarization process.

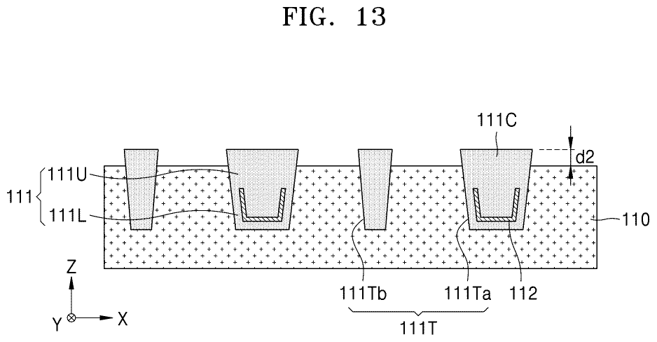

Referring to FIG. 13, the pad insulation layer 102 (refer to FIG. 12) may be removed to expose the top surface of the substrate 110. The pad insulation layer 102 may be removed through a stripping process, but the inventive concept is not limited thereto.

According to embodiments of the present disclosure, as the pad insulation layer 102 is removed, the device isolating insulation pattern 111 may include a protrusion 111C that protrudes in the vertical direction (Z direction) more than the top surface of the substrate 110. The protrusion 111C may extend in the vertical direction (Z direction) from the upper insulation pattern 111U. At this time, a distance d₂ from the top surface of the substrate 110 to the top surface of the protrusion 111C may be from about 10 Å to about 300 Å, but the inventive concept is not limited thereto.

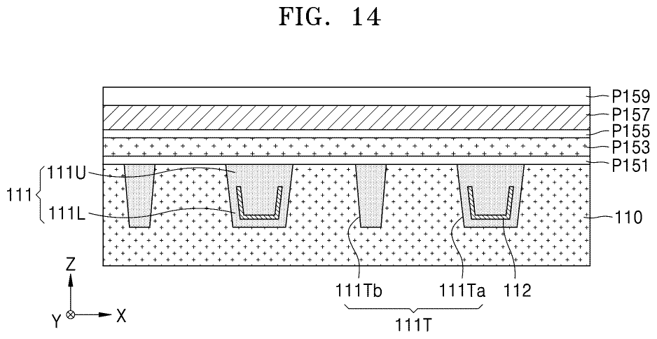

Referring to FIG. 14, the protrusion 111C may be removed from a resulting structure of FIG. 13. After forming an oxide film covering the top surface of the substrate 110 and at least a portion of the protrusion 111C, the protrusion 111C may be removed through a planarization process.

Thereafter, a gate insulation layer P151, a first conductive layer P153, a second conductive layer P155, a third conductive layer P157, and a capping layer P159 may be sequentially formed to cover the top surface of the substrate 110 and the top surface of the device isolating insulation pattern 111.

According to embodiments of the present disclosure, since the liner pattern 112 is not disposed within the upper insulation pattern 111U, the top surface of the device isolating insulation pattern 111 may form a coplanar shape therewith. Accordingly, since the top surface of the device isolating insulation pattern 111 does not form a recessed portion, the gate insulation layer P151, the first conductive layer P153, the second conductive layer P155, the third conductive layer P157, and the capping layer P159 may be formed flat.

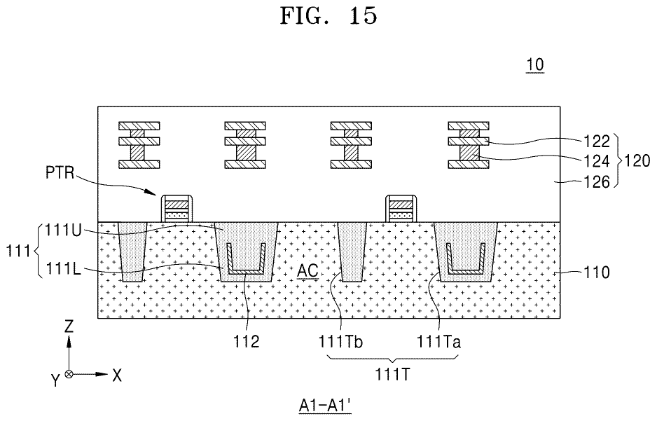

Referring to FIG. 15, the gate insulation layer P151, the first conductive layer P153, the second conductive layer P155, the third conductive layer P157, and the capping layer P159 may be patterned to form the transistor PTR on the active region AC.

According to embodiments of the present disclosure, since the liner pattern 112 is not disposed within the upper insulation pattern 111U, the top surface of the device isolating insulation pattern 111 may form a coplanar shape. Accordingly, since the top surface of the device isolating insulation pattern 111 does not form a recessed portion, defects may be prevented from occurring in the process of forming the transistor PTR on the active region AC through the patterning.

Thereafter, the wiring structure 120 may be formed to cover the transistor PTR on the substrate 110, thereby fabricating the semiconductor device 10 of the inventive concept. The wiring structure 120 may include the wire 122, the contact 124, and the insulation layer 126.

Also, referring to FIG. 6, the semiconductor device 100 may be fabricated by bonding the semiconductor device 10 corresponding to a peripheral circuit region PCA to the cell array region MCA.

While the inventive concept has been particularly shown and described with reference to embodiments of the present disclosure thereof, it will be understood that various changes in form and details may be made therein without departing from the spirit and scope of the following claims.

1. A method of manufacturing a semiconductor device, the method comprising:
forming a pad insulation layer and a mask structure on a substrate;
etching the pad insulation layer and the mask structure to form a plurality of trenches;
forming a first oxide film on the plurality of trenches;
forming a liner layer on the first oxide film, the liner layer comprising silicon nitride;
forming a second oxide film on the liner layer;
forming a device isolating insulation layer covering a top surface of the substrate by changing the liner layer into an oxide through a densification process; and
forming a device isolating insulation pattern that fills the plurality of trenches by removing a portion of the device isolating insulation layer through a planarization process.

2. The method of claim 1, wherein:
the forming of the first oxide film is performed through an atomic layer deposition process; and
the forming of the second oxide film is performed through a chemical vapor deposition process.

3. The method of claim 1, wherein the device isolating insulation pattern comprises:
a lower insulation pattern covering a bottom surface and a portion of a sidewall of the trenches and comprising silicon oxide;
an upper insulation pattern covering the lower insulation pattern, filling the trenches, and comprising silicon oxide; and
a liner pattern provided within the lower insulation pattern below the upper insulation pattern and comprising silicon nitride.

4. The method of claim 3, wherein the densification process changes a portion of the liner layer provided within the upper insulation pattern into an oxide, with a portion of the liner layer remaining after the densification process forming the liner pattern.

5. The method of claim 3, wherein the densification process changes a portion of the liner layer provided within the lower insulation pattern into an oxide, with a portion of the liner layer remaining after the densification process forming the liner pattern.

6. The method of claim 3, wherein:
80% or more of the device isolating insulation pattern comprises silicon oxide; and
95% or more of the upper insulation pattern comprises silicon oxide.

7. The method of claim 3, wherein a thickness of the liner pattern is 70 Å or less.

8. The method of claim 3, wherein a vertical distance between a top surface of the upper insulation pattern and a top surface of the lower insulation pattern is within 50 Å.

9. The method of claim 1, further comprising removing a portion of the pad insulation layer remaining after the planarization process such that a one or more protrusions are formed in the device isolating insulation pattern, the one or more protrusions protruding beyond the top surface of the substrate.

10. The method of claim 9, further comprising:
removing the one or more protrusions to planarize a top surface of the device isolating insulation pattern to be coplanar with the top surface of the substrate; and
forming a gate electrode on the substrate.

11. A method of manufacturing a semiconductor device, the method comprising:
forming a pad insulation layer and a mask structure on a substrate;
etching the pad insulation layer and the mask structure to form a plurality of trenches;
forming a first oxide film conformally covering the plurality of trenches through an atomic layer deposition process on the plurality of trenches;
forming a liner layer on the first oxide film, the liner layer comprising silicon nitride;
forming a second oxide film filling the plurality of trenches through a chemical vapor deposition process on the liner layer;
consuming at least a portion of the liner layer through a densification process; and
forming a device isolating insulation pattern that fills the plurality of trenches by removing the pad insulation layer, the first oxide film, and the second oxide film.

12. The method of claim 11, wherein the consuming of the liner layer changes the at least a portion of the liner layer provided within the device isolating insulation pattern into an oxide.

13. The method of claim 12, wherein, in the consuming of the liner layer, an amount of the at least a portion of the liner layer that is changed into the oxide increases as a distance from a bottom surface of a trench increases.

14. The method of claim 11, wherein, in the consuming of the liner layer, the at least a portion of the liner layer is changed into an oxide, and a portion of the liner layer not changed into an oxide is formed into a liner pattern comprising silicon nitride.

15. The method of claim 14, wherein the liner pattern is provided within a lower insulation pattern of the device isolating insulation pattern below an upper insulation pattern of the device isolating insulation pattern and has a U-shaped vertical cross-section.

16. The method of claim 14, wherein a vertical distance between a topmost portion of the liner pattern and a top surface of the device isolating insulation pattern is within 50 Å.

17. A method of manufacturing a semiconductor device, the method comprising:
preparing a cell array region comprising a memory cell array;
preparing a peripheral circuit region comprising a peripheral circuit transistor for transmitting a signal and power to the memory cell array;
attaching the cell array region and the peripheral circuit region in a vertical direction; and
wherein the preparing of the peripheral circuit region comprises:
sequentially forming a pad insulation layer and a mask structure on a substrate;
etching the pad insulation layer and the mask structure to form a plurality of trenches;
forming a first oxide film conformally covering the plurality of trenches through an atomic layer deposition process on the plurality of trenches;
forming a liner layer on the first oxide film, the liner layer comprising silicon nitride;
forming a second oxide film filling the plurality of trenches through a chemical vapor deposition process on the liner layer;
forming a device isolating insulation layer covering a top surface of the substrate by changing the liner layer into an oxide through a densification process; and
forming a device isolating insulation pattern that fills the plurality of trenches by removing a portion of the device isolating insulation layer through a planarization process.

18. The method of claim 17, wherein the device isolating insulation pattern comprises:
a lower insulation pattern covering a bottom surface and a portion of a sidewall of the trenches and comprising silicon oxide;
an upper insulation pattern covering the lower insulation pattern, filling the trenches, and comprising silicon oxide; and
a liner pattern provided within the lower insulation pattern below the upper insulation pattern and comprising silicon nitride.

19. The method of claim 17, wherein the forming of the device isolating insulation layer changes a portion of the liner layer provided within the lower insulation pattern into an oxide.

20. The method of claim 17, wherein:
80% or more of the device isolating insulation pattern comprises silicon oxide; and
95% or more of the upper insulation pattern comprises silicon oxide.

21.-30. (canceled)
